(19) United States
(12) Patent Application Publication
(10) Pub. No.: US 2025/0248101 A1
(43) Pub. Date: Jul. 31, 2025

(54) TOP SACRIFICIAL RIBBON STRUCTURE FOR GATE ALL AROUND DEVICE ARCHITECTURE

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/429,045

(22) Filed: Jan. 31, 2024

(51) Int. Cl. H01L 29/417; H01L 29/06; H01L 29/423; H01L 29/66; H01L 29/775; H01L 29/786

(52) U.S. Cl. CPC H10D 64/258; H10D 30/014; H10D 30/43; H10D 30/6735; H10D 30/6757; H10D 62/121

(57) ABSTRACT

A field effect transistor (FET) structure and method for making the same is disclosed. In an aspect, a FET structure comprises a vertical metal gate disposed between a first and second source/drain (S/D) epitaxial (EPI) structure and having a set of vertically-stacked, horizontal channels, all but the top channel connecting the first and second S/D EPI structures through the vertical metal gate. A high-K dielectric material is disposed between the vertical metal gate and each of the horizontal channels, and vertical spacer layers separate the vertical metal gate from the S/D EPI structures. A low-K dielectric structure is disposed above the top-most portion of the vertical metal gate and fills a recess above the vertical metal gate and between the first vertical spacer layer and the second vertical spacer layer.

### BACKGROUND OF THE DISCLOSURE

### 1. Field of the Disclosure

This disclosure relates generally to semiconductor wafer process, and more specifically to gate-all-around (GAA) field effect transistors (FETs) structures and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a field effect transistor (FET) structure includes a first source/drain (S/D) epitaxial (EPI) structure and a second S/D EPI structure set apart in a second horizontal direction; a vertical metal gate structure, extending in a first horizontal direction, being disposed between the first S/D EPI structure and the second S/D EPI structure, and comprising a channel structure, the channel structure comprising a plurality of nanosheet ribbons set apart in a vertical direction and extending in the first horizontal direction between the first S/D EPI structure and the second S/D EPI structure through the vertical metal gate structure that at least partially surrounds the plurality of nanosheet ribbons, wherein a top-most nanosheet ribbon of the plurality of nanosheet ribbons does not form a complete path to electrically connect the first S/D EPI structure to the second S/D EPI structure and wherein each of the other nanosheet ribbons of the plurality of nanosheet ribbons forms a complete path to electrically connect the first S/D EPI structure to the second S/D EPI structure; a high-K dielectric material disposed between the vertical metal gate structure and each of the plurality of nanosheet ribbons; a first vertical spacer layer extending in the first horizontal direction and disposed between the vertical metal gate structure and the first S/D EPI structure; a second vertical spacer layer extending in the first horizontal direction and disposed between the vertical metal gate structure and the second S/D EPI structure; and a low-K dielectric structure disposed above a top-most portion of the vertical metal gate structure and between the first vertical spacer layer and the second vertical spacer layer.

In an aspect, a method of fabricating a FET structure includes providing a first S/D EPI structure and a second S/D EPI structure set apart in a second horizontal direction; providing a vertical metal gate structure, extending in a first horizontal direction, being disposed between the first S/D EPI structure and the second S/D EPI structure, and comprising a channel structure, the channel structure comprising a plurality of nanosheet ribbons set apart in a vertical direction and extending in the first horizontal direction between the first S/D EPI structure and the second S/D EPI structure through the vertical metal gate structure that at least partially surrounds the plurality of nanosheet ribbons, wherein a top-most nanosheet ribbon of the plurality of nanosheet ribbons does not form a complete path to electrically connect the first S/D EPI structure to the second S/D EPI structure and wherein each of the other nanosheet ribbons of the plurality of nanosheet ribbons forms a complete path to electrically connect the first S/D EPI structure to the second S/D EPI structure; providing a high-K dielectric material disposed between the vertical metal gate structure and each of the plurality of nanosheet ribbons; providing a first vertical spacer layer extending in the first horizontal direction and disposed between the vertical metal gate structure and the first S/D EPI structure; providing a second vertical spacer layer extending in the first horizontal direction and disposed between the vertical metal gate structure and the second S/D EPI structure; and providing a low-K dielectric structure disposed above a top-most portion of the vertical metal gate structure and between the first vertical spacer layer and the second vertical spacer layer.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIGS. 1A and 1B are a top view and a cross-sectional view, respectively, of a semiconductor structure of an integrated circuit (IC) device with conventional gate-all-around (GAA) field effect transistors (FETs).

FIG. 2 is a cross-sectional view of a semiconductor structure comprising top sacrificial ribbon (TSR) GAA FETs, according to aspects of the disclosure.

FIGS. 3A through 3I are cross-sections that illustrate steps in a process for fabricating a semiconductor structure with TSR GAA FETs, according to aspects of the disclosure.

FIG. 4 is a flowchart showing a portion of a simplified wafer process for fabricating a semiconductor structure having TSR GAA FETs, according to aspects of the disclosure.

FIG. 5 is a flowchart of an example process associated with TSR GAA FETs, according to aspects of the disclosure.

FIG. 6 illustrates a mobile device in accordance with some examples of the disclosure.

FIG. 7 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

A field effect transistor (FET) structure having recessed source/drain (S/D) epitaxial (EPI) structures for direct backside contact and methods for making the same are disclosed. In an aspect, a FET structure comprises a first source/drain (S/D) epitaxial (EPI) structure and a second S/D EPI structure set apart in a second horizontal direction, and a vertical metal gate structure, extending in a first horizontal direction, being disposed between the first S/D EPI structure and the second S/D EPI structure. The vertical metal gate structure comprises a channel structure, the channel structure comprising a plurality of nanosheet ribbons set apart in a vertical direction and extending in the first horizontal direction between the first S/D EPI structure and the second S/D EPI structure through the vertical metal gate structure that at least partially surrounds the plurality of nanosheet ribbons, wherein a top-most nanosheet ribbon of the plurality of nanosheet ribbons does not form a complete path to electrically connect the first S/D EPI structure to the second S/D EPI structure and wherein each of the other nanosheet ribbons of the plurality of nanosheet ribbons forms a complete path to electrically connect the first S/D EPI structure to the second S/D EPI structure. A high-K dielectric material is disposed between the vertical metal gate structure and each of the plurality of nanosheet ribbons. A first vertical spacer layer extends in the first horizontal direction and is disposed between the vertical metal gate structure and the first S/D EPI structure; a second vertical spacer layer extends in the first horizontal direction and is disposed between the vertical metal gate structure and the second S/D EPI structure; and a low-K dielectric structure is disposed above a top-most portion of the vertical metal gate structure and between the first vertical spacer layer and the second vertical spacer layer. In some aspects, this structure is fabricated by first fabricating a nanosheet FET having N nanosheet channels, growing EPI using the exposed ends of the silicon nanosheet channels, then removing the top-most silicon nanosheet channel and metal gate finger and filling that area with a low-K dielectric. Thus, a frontside S/D contact to the S/D EPI structure will not get very close to either the metal gate or the channel.

As used herein, the term “low-K” refers to a material that has a K value between 2.5 and 4.5. Examples of low-K materials include silicon dioxide (SiO₂), which has a K value of 3.9, as well as silicon carbon oxynitride (SiCON) and silicon carbonate (SiCO). As used herein, the term “high-K” refers to a material that has a K value that is higher than SiO₂, e.g., having a K value that is greater than 7. Examples of high-K materials include, but are not limited to, hafnium oxide (HfOₓ), which has a K value of approximately 15 to 25.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Particular aspects of the subject matter described in this disclosure can be implemented to realize one or more of the following potential advantages. Because the recessed S/D EPI structures extend below the gate structures, S/D contacts are far enough away from the gate structures that there is less chance that a process error (e.g., an etch process that etched too deep, a lithography process that was not completely aligned to the wafer, etc.) will cause the S/D contact to short circuit with the gate. Also, since the contact does not have to fit solely within the space between adjacent gates, a S/D contact can be made with a larger surface area, which reduces contact resistance.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

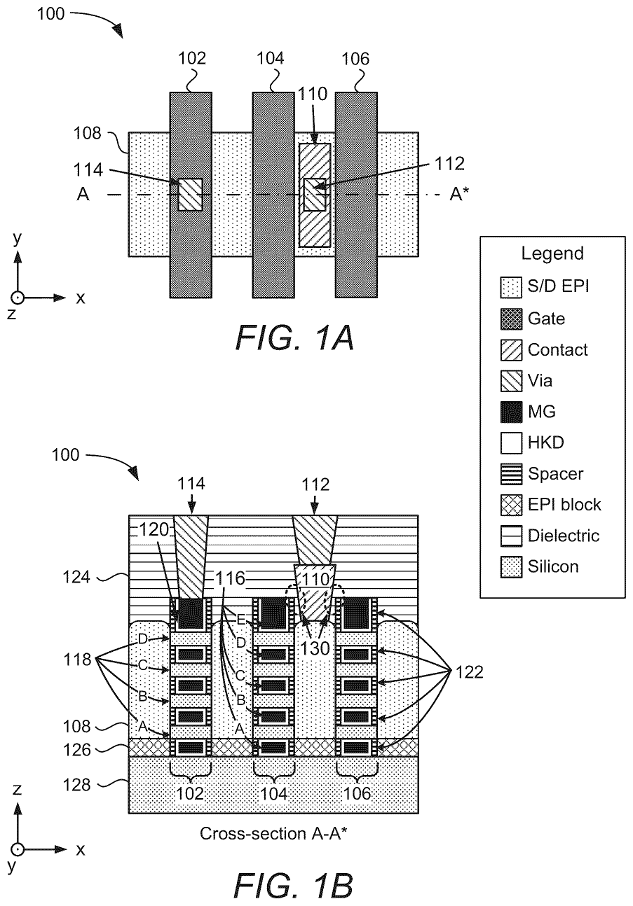

FIG. 1A is a top view of a portion of a semiconductor structure 100 of an integrated circuit (IC) device with conventional gate-all-around (GAA) field effect transistors (FETs). In some aspects, FIG. 1A merely shows some elements of the semiconductor structure 100 for illustration purposes, and other elements above and/or below the elements shown in FIG. 1A may be disposed but not shown in FIG. 1A. As shown in FIG. 1A, the semiconductor structure 100 includes gate stacks 102, 104, and 106 spaced along a first direction (e.g., the x direction) and having a length along a second direction (e.g., the y direction). As used herein, the term “gate stack” refers to a structure that includes a metal gate and which may also include dielectric material, an inner spacer, and other structural components. As used herein, the terms “gate” and “gate stack” are synonymous unless specifically indicated as otherwise. The semiconductor structure 100 also includes a region of epitaxial (EPI) source/drain (S/D) structures 108 between the gate stacks. The semiconductor structure 100 also includes an S/D contact 110, an S/D via (Vs) 112 and a gate via (Vg) 114. The S/D contact 110, S/D via 112 and gate via 114 are all frontside contacts (FSCs).

FIG. 1B is a cross-sectional view of the semiconductor structure 100 along cut-line A-A *. As can be seen in FIG. 1B, each gate cross-section includes a metal gate structure 116 through which one or more channels 118 extend, insulated from the gate metal by a dielectric 120 and insulated from the EPI structures by an inner spacer 122. In the example shown in FIG. 1B, there are four channels 118, labeled A through D, with D being the top channel. The metal gate structure 116 has five horizontal metal “fingers”, labeled A through E, with E being the top finger. As shown in FIG. 1B, a frontside dielectric stack 124, which may include one or more dielectric layers, one or more of which may be an inter-layer dielectric (ILD) layer, covers the tops of the gate stacks and EPI regions. It is through this dielectric stack 124 that the S/D contact 110, S/D via 112, and gate via 114 extend. As shown in FIG. 1B, an EPI block or etch stop layer 126 surrounds the bottom portion of each gate, all of which sit atop a silicon substrate 128. The etch stop layer 126 is omitted in processes which do not use backside connectivity or that for other reasons do not remove the substrate as part of the fabrication process.

FIG. 1B also illustrates a disadvantage of this conventional structure-namely, that patterning steps (mask, etch, etc.) to create the S/D contact 110 must be precise enough so that the S/D contact 110 does not unintentionally make contact with the gate stacks on either side, e.g., in the areas labeled 130 in FIG. 1B. To ensure that this does not happen, conventional processes constrain the side-to-side dimensions of S/D contacts, which result in a smaller S/D contact with higher resistance. These constraints also are a barrier to reduction of layout size, since S/D contacts and the gate stacks on either side would get even closer to each other as the chip dimensions are scaled down.

To address these issues, a top sacrificial ribbon (TSR) GAA FET design is presented herein.

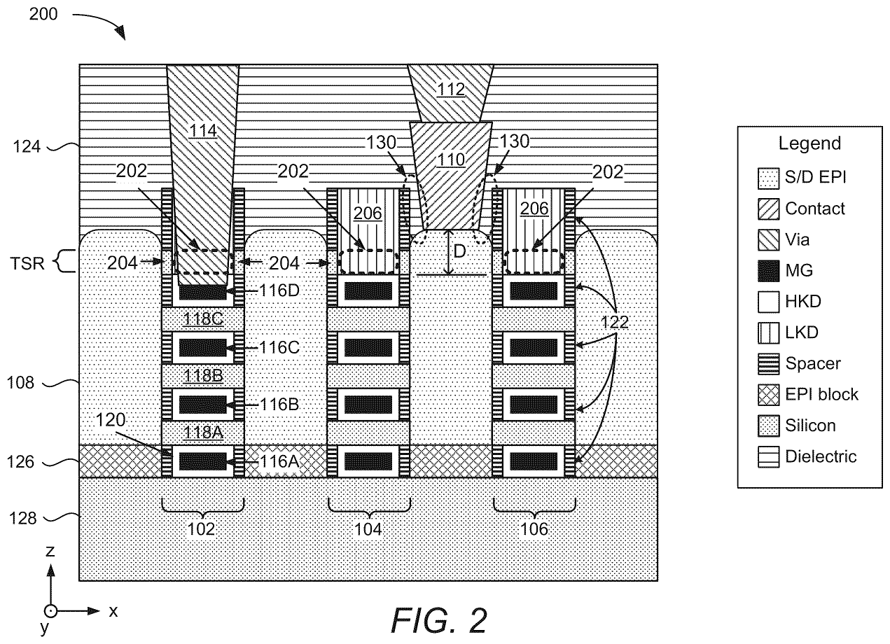

FIG. 2 is a cross-sectional view of a semiconductor structure 200 comprising top sacrificial ribbon (TSR) GAA FETs, according to aspects of the disclosure. Numbered elements in FIG. 2 are the same or similar to their like-numbered elements in FIG. 1, and the descriptions thereof will not be repeated here for brevity. FIG. 2 shows a cross-section of gate 102, gate 104, and gate 106. In FIG. 2, however, the top channel 118D, which may also be referred to herein as the TSR, has been sacrificed, i.e., the top channel 118D was created so that its silicon would provide a seed for S/D EPI growth—and was used for that purpose during the EPI formation process—but was later subjected to an etch process that removed at least a portion of the top channel 118D-shown in FIG. 2 as area 202—leaving only remnants 204. In some aspects, the remnants 204 are the ends of the silicon channel 118D that were not etched away. In some aspects, the entire silicon channel 118D is etched away, in which case the remnants 204 are layers of dielectric fill that are artifacts from the deposit-etch-deposit (D-E-D) process that was used to remove the material in area 202, which leaves dielectric material at the sidewall corner. In some aspects, the remnants 204 are a combination of silicon remaining from the channel and layers of dielectric fill from the D-E-D process. The use of a TSR ensures that the EPI structures 108 are tall enough that the vertical distance (labeled as “D” in FIG. 2) from a subsequently formed frontside S/D contact metal to the metal gate structure is sufficiently large that misalignment of the frontside S/D contact does not result in an unintentional short with the gate metal.

As shown in FIG. 2, the cavity between the inner spacers 122 that, in the semiconductor structure 100 in FIG. 1, was occupied by the top channel 118D and the top metal finger 116E instead contains a low-K dielectric (LKD) structure 206. The dielectric stack 124 may comprise a first layer that is formed to cover the tops of the EPI S/D structures 108 up to the top of the inner spacers 122 (e.g., using a patterning, deposition, and CMP process) and a second layer that extends above the tops of the inner spacers 122 and LKD structures 206. As can be seen in FIG. 2, the gate via 114 extends further down between the inner spacers 122 to reach the now top-most metal finger 116D.

The semiconductor structure 200 has a number of advantages over the conventional semiconductor structure 100. For example, as can be seen in FIG. 2, the S/D contact 110 is much farther away from the closed metal gate fingers 116D and thus, even if the S/D contact 110 encroaches into the areas 130, there is no possibility for an unintentional short between the S/D contact 110 and the metal gate structures of gate 104 or the gate 106.

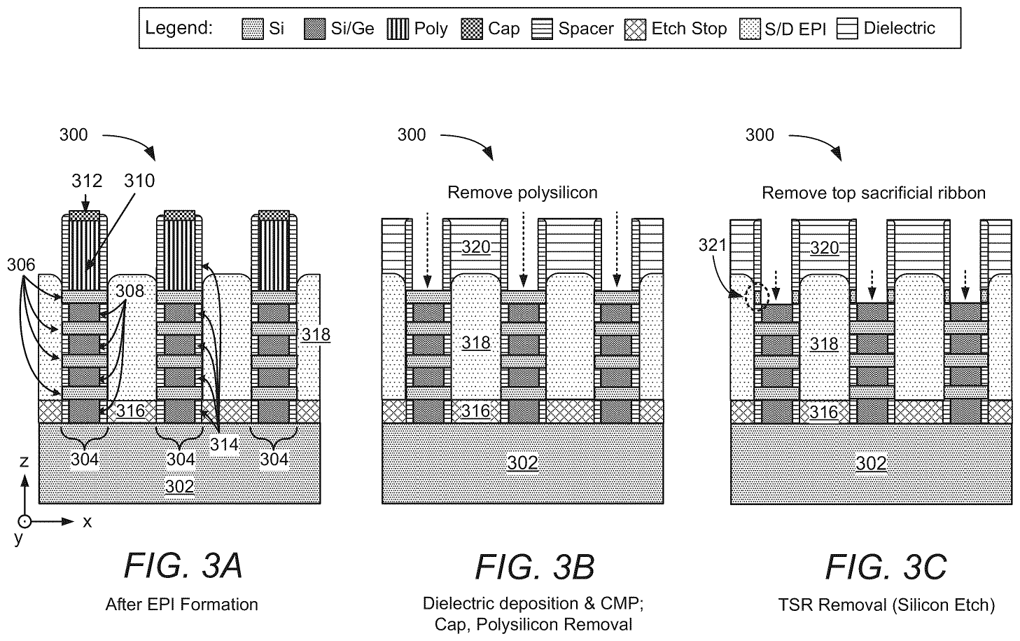

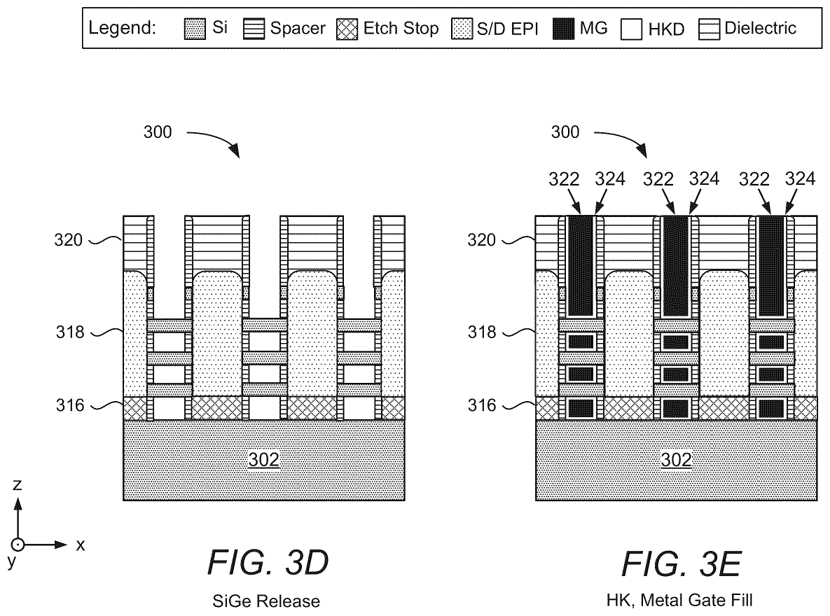

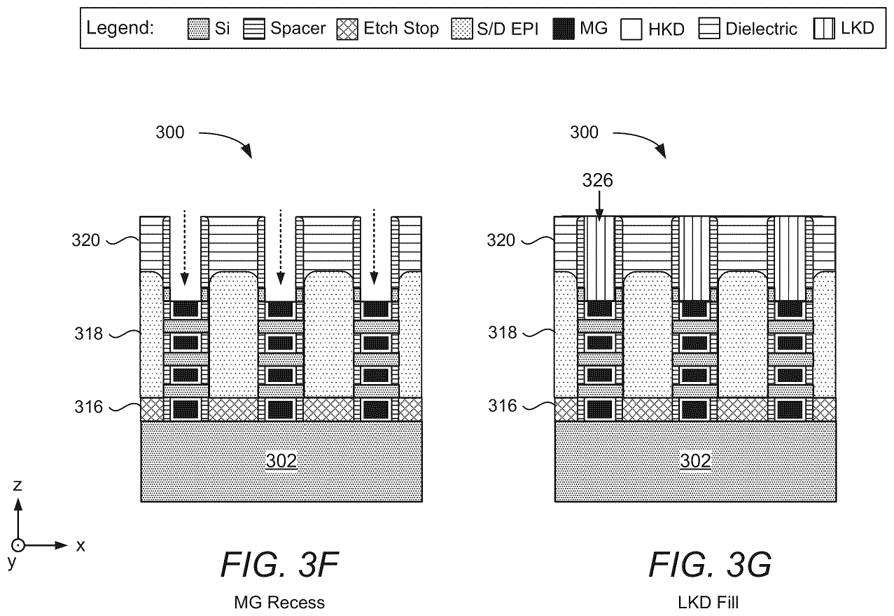

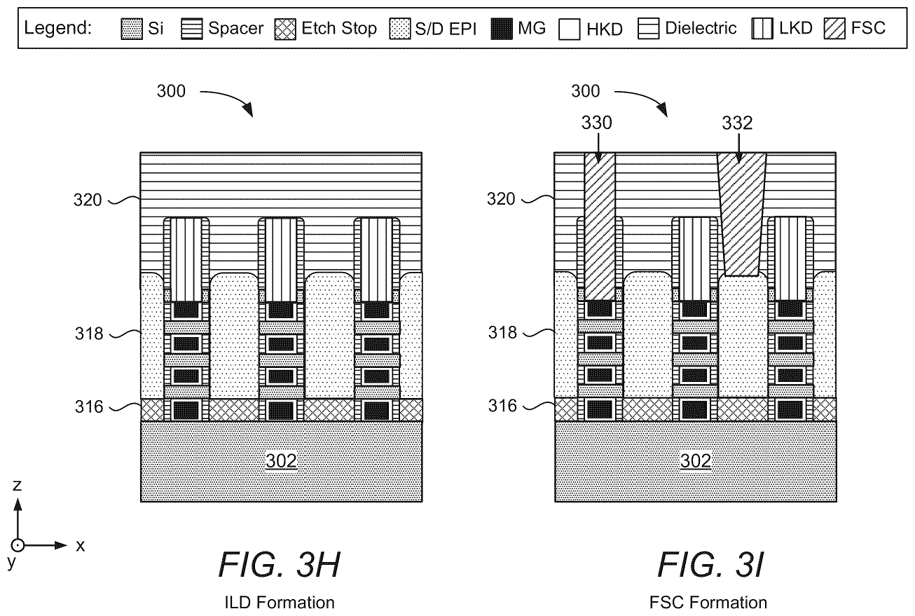

FIGS. 3A-3I are cross-sections that illustrate steps in a process for fabricating a semiconductor structure having TSR GAA FETs, according to aspects of the disclosure. As shown in FIG. 3A, the process starts with a semiconductor structure 300 comprising a silicon substrate 302 upon which have been fabricated a set of gate stacks 304, each gate stack comprising alternating layers of silicon (Si) and silicon/germanium (Si/Ge). The silicon layers 306 will become the channels and the Si/Ge layers 308 will be later replaced by a metal gate. Each gate stack 304 is topped with a polysilicon structure 310 and a cap structure 312 (e.g., a dielectric material). Each gate stack 304 has been subjected to a process to create lateral recesses in which an inner spacer 314 has been deposited.

The semiconductor structure 300 has been further subjected to process to deposit an etch stop structure 316, which may be a film, at the bottom of each recess, and to grow EPI structures 318 between each gate stack 304. Materials that can be used for the etch stop structure 316 include, but are not limited to, titanium silicide (TiSi), silicon carbon nitride (SiCN), silicon carbon oxynitride (SiCON), aluminum nitride (AlN), area-selective deposition (ASD) dielectrics, SiGe EPI, and other materials that have high etch selectivity to spacer and later backside Si removal.

FIG. 3B illustrates the result after deposition and chemical/mechanical polishing (CMP) of a dielectric layer 320 and removal of the gate cap structures 312 and polysilicon structures 310.

FIG. 3C illustrates the result after a silicon etch process to remove the TSR, i.e., the top-most channel of the silicon layers 306. In some aspects, a remnant 321 of the silicon channel may remain after the etch process. In some aspects, the silicon channel may be entirely removed, leaving no remnant. In some aspects, the silicon channel may be entirely removed, but the silicon etch process used to remove the TSR leaves a remnant 321 of dielectric material in this location.

FIG. 3D illustrates the result after a SiGe release process, during which the Si/Ge layers 308 are removed.

FIG. 3E illustrates the result after a replacement metal gate (RMG) process that includes forming multi-fingered metal gate (MG) structures 322 and high-K dielectric (HKD) structures 324.

FIG. 3F illustrates the result after a process that creates a deep recess in the top portions of the MG structures 322. In some aspects, the deep recess removes all but 2-3 nm of the top “finger” of the multi-finger MG structure 322.

FIG. 3G illustrates the result after deposition of a low-K dielectric (LKD) within the top gate recesses to create a set of LKD structures 326.

FIG. 3H illustrates the result after deposition of an additional dielectric layer to the dielectric stack 320 (or after the additional growth of the dielectric stack 320), which may comprise formation of an ILD layer and CMP.

FIG. 31 illustrates the result after creation of a frontside gate contact 330 and a frontside S/D contact 332.

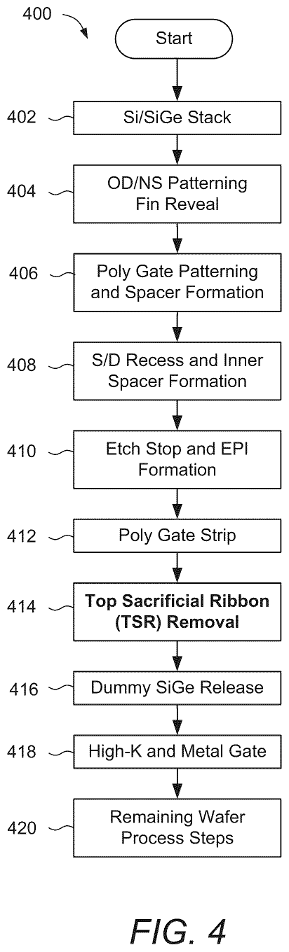

FIG. 4 is a flowchart showing a portion of a simplified wafer process for fabricating a semiconductor structure having TSR GAA FETs, according to aspects of the disclosure. As shown in FIG. 4, the process 400 may include, at block 402, forming the Si/SiGe stack, e.g., depositing the alternating layers of silicon 306 and Si/Ge 308 shown in FIG. 3A.

The process 400 may include, at block 404, performing oxide diffusion/nanosheet patterning and fin reveal, and at block 406, polysilicon gate patterning, e.g., to produce the polysilicon structures 310 and the cap structures 312 shown in FIG. 3A.

The process 400 may include, at block 408, S/D recess and inner spacer formation, e.g., by etching the alternating Si and Si/Ge layers to create the gate stacks 304 with lateral recesses and the inner spacers 314 shown in FIG. 3A.

The process 400 may include, at block 410, deposition of an etch stop layer and formation of EPI structures, e.g., the etch stop structures 316 and the EPI structures 318 shown in FIG. 3A.

The process 400 may include, at block 412, a poly gate strip process, e.g., as shown in FIG. 3B.

The process 400 may include, at block 414, removal of the top sacrificial ribbon, e.g., as shown in FIG. 3C.

The process 400 may include, at block 416, a dummy SiGe release process, e.g., as shown in FIG. 3D.

The process 400 may include, at block 418, a high-K dielectric and metal gate process, e.g., as shown in FIG. 3E.

The process 400 may include, at block 420, performing the remaining wafer process steps, e.g., the MG recess etch shown in FIG. 3F, the LKD fill shown in FIG. 3G, the ILD formation shown in FIG. 3H, and the FSC formation shown in FIG. 3I.

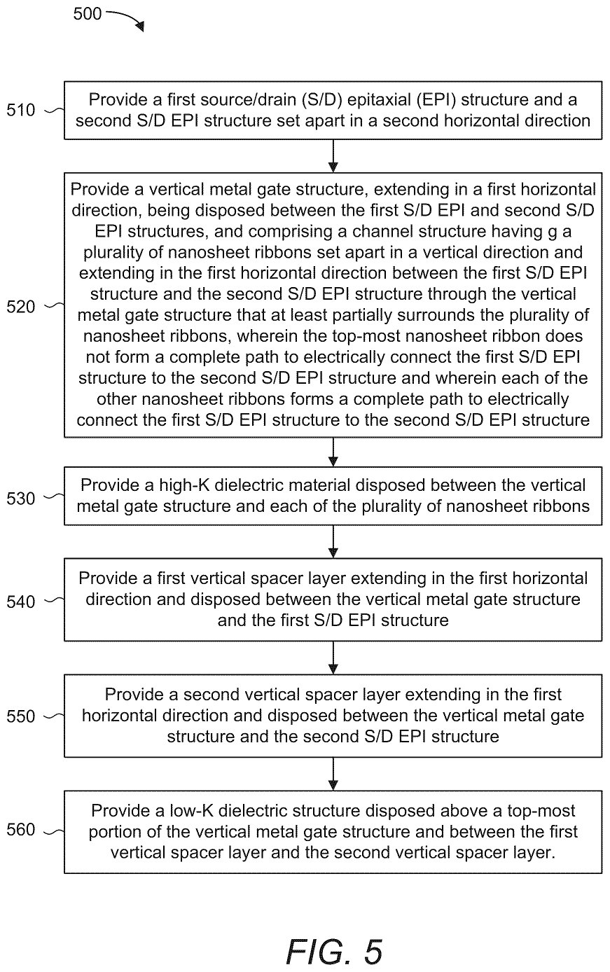

FIG. 5 is a flowchart of an example process 500 associated with TSR GAA FETs, according to aspects of the disclosure. As shown in FIG. 5, process 500 may include, at block 510, providing a first S/D EPI structure and a second S/D EPI structure set apart in a second horizontal direction. As further shown in FIG. 5, process 500 may include, at block 520, providing a vertical metal gate structure, extending in a first horizontal direction, being disposed between the first S/D EPI structure and the second S/D EPI structure, and comprising a channel structure, the channel structure comprising a plurality of nanosheet ribbons set apart in a vertical direction and extending in the first horizontal direction between the first S/D EPI structure and the second S/D EPI structure through the vertical metal gate structure that at least partially surrounds the plurality of nanosheet ribbons, wherein a top-most nanosheet ribbon of the plurality of nanosheet ribbons does not form a complete path to electrically connect the first S/D EPI structure to the second S/D EPI structure and wherein each of the other nanosheet ribbons of the plurality of nanosheet ribbons forms a complete path to electrically connect the first S/D EPI structure to the second S/D EPI structure.

As further shown in FIG. 5, process 500 may include, at block 530, providing a high-K dielectric material disposed between the vertical metal gate structure and each of the plurality of nanosheet ribbons.

As further shown in FIG. 5, process 500 may include, at block 540, providing a first vertical spacer layer extending in the first horizontal direction and disposed between the vertical metal gate structure and the first S/D EPI structure.

As further shown in FIG. 5, process 500 may include, at block 550, providing a second vertical spacer layer extending in the first horizontal direction and disposed between the vertical metal gate structure and the second S/D EPI structure.

As further shown in FIG. 5, process 500 may include, at block 560, providing a low-K dielectric structure disposed above a top-most portion of the vertical metal gate structure and between the first vertical spacer layer and the second vertical spacer layer.

In some aspects, the top-most nanosheet ribbon of the plurality of nanosheet ribbons comprises a first portion that contacts the first S/D EPI structure and a second portion that contacts the second S/D EPI structure but does not contact the first portion.

In some aspects, at least one of the first portion or the second portion comprises silicon, dielectric, or a combination thereof.

In some aspects, the low-K dielectric structure extends between the first and second portions of the top-most nanosheet ribbon of the plurality of nanosheet ribbons.

In some aspects, process 500 includes providing a frontside gate contact disposed between the first vertical spacer and the second vertical spacer and extending through the low-K dielectric structure to contact the vertical metal gate structure.

In some aspects, process 500 includes providing a frontside inter-layer dielectric (ILD) layer disposed above the vertical metal gate structure, the first S/D EPI structure, and the second S/D EPI structure.

In some aspects, process 500 includes providing a frontside S/D contact extending through the frontside ILD layer to contact the first S/D EPI structure or the second S/D EPI structure.

In some aspects, process 500 includes providing an etch stop material disposed on at least a bottom surface of the lower portion of the second S/D EPI structure.

In some aspects, providing the etch stop material comprises providing at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

In some aspects, process 500 includes providing a backside ILD layer disposed below the vertical metal gate structure, the first S/D EPI structure, and the second S/D EPI structure.

In some aspects, providing the vertical metal gate structure comprises providing a gate-all-around (GAA) structure.

In some aspects, providing the vertical metal gate structure comprises forming a stack of alternating silicon (Si) and silicon germanium (SiGe) layers, patterning the stack to form the silicon layers into silicon nanosheets separated by SiGe layers, etching the stack to create a gate stack between source/drain recesses, growing EPI structures from exposed silicon layers of the gate stack, removing a top-most silicon nanosheet, and performing a replacement metal gate process to replace the SiGe layers with gate metal.

Process 500 may include additional implementations, such as any single implementation or any combination of implementations described below and/or in connection with one or more other processes described elsewhere herein.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

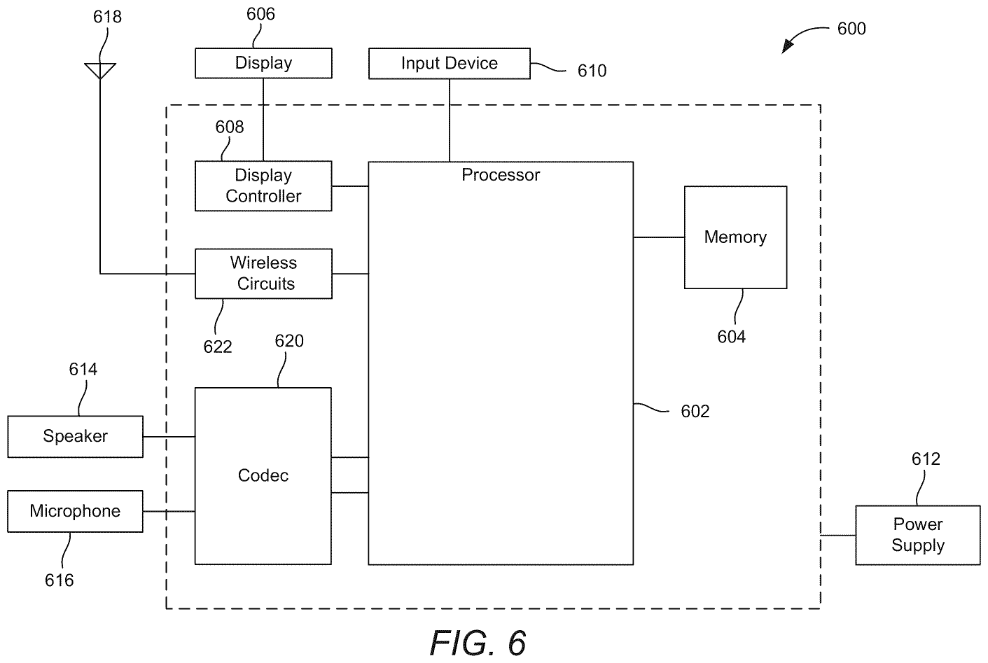

FIG. 6 illustrates a mobile device 600, according to aspects of the disclosure. In some aspects, the mobile device 600 may be implemented by including one or more IC devices manufactured based on the examples described in this disclosure.

In some aspects, mobile device 600 may be configured as a wireless communication device. As shown, mobile device 600 includes processor 602. Processor 602 may be communicatively coupled to memory 604 over a link, which may be a die-to-die or chip-to-chip link. Mobile device 600 also includes display 606 and display controller 608, with display controller 608 coupled to processor 602 and to display 606. The mobile device 600 may include input device 610 (e.g., physical, or virtual keyboard), power supply 612 (e.g., battery), speaker 614, microphone 616, and wireless antenna 618. In some aspects, the power supply 612 may directly or indirectly provide the supply voltage for operating some or all of the components of the mobile device 600.

In some aspects, FIG. 6 may include coder/decoder (CODEC) 620 (e.g., an audio and/or voice CODEC) coupled to processor 602; speaker 614 and microphone 616 coupled to CODEC 620; and wireless circuits 622 (which may include a modem, RF circuitry, filters, etc.) coupled to wireless antenna 618 and to processor 602.

In some aspects, one or more of processor 602, display controller 608, memory 604, CODEC 620, and wireless circuits 622 may include one or more IC devices including semiconductor structures manufactured according to the examples described in this disclosure.

It should be noted that although FIG. 6 depicts a mobile device 600, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

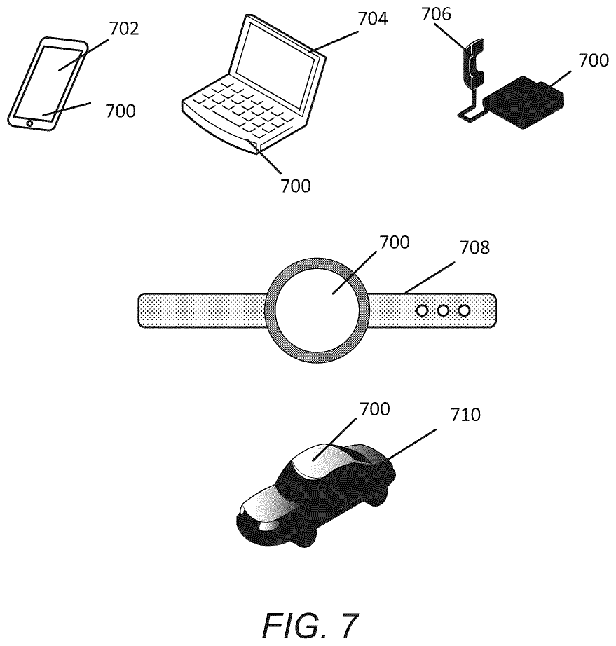

FIG. 7 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 702, a laptop computer device 704, a fixed location terminal device 706, a wearable device 708, or automotive vehicle 710 may include a semiconductor device 700 (e.g., semiconductor structure 200, semiconductor structure 300) as described herein. The devices 702, 704, 706 and 708 and the vehicle 710 illustrated in FIG. 7 are merely exemplary. Other apparatuses or devices may also feature the semiconductor device 700 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:
Clause 1. A field effect transistor (FET) structure, comprising: a first source/drain (S/D) epitaxial (EPI) structure and a second S/D EPI structure set apart in a second horizontal direction; a vertical metal gate structure, extending in a first horizontal direction, being disposed between the first S/D EPI structure and the second S/D EPI structure, and comprising a channel structure, the channel structure comprising a plurality of nanosheet ribbons set apart in a vertical direction and extending in the first horizontal direction between the first S/D EPI structure and the second S/D EPI structure through the vertical metal gate structure that at least partially surrounds the plurality of nanosheet ribbons, wherein a top-most nanosheet ribbon of the plurality of nanosheet ribbons does not form a complete path to electrically connect the first S/D EPI structure to the second S/D EPI structure and wherein each of the other nanosheet ribbons of the plurality of nanosheet ribbons forms a complete path to electrically connect the first S/D EPI structure to the second S/D EPI structure; a high-K dielectric material disposed between the vertical metal gate structure and each of the plurality of nanosheet ribbons; a first vertical spacer layer extending in the first horizontal direction and disposed between the vertical metal gate structure and the first S/D EPI structure; a second vertical spacer layer extending in the first horizontal direction and disposed between the vertical metal gate structure and the second S/D EPI structure; and a low-K dielectric structure disposed above a top-most portion of the vertical metal gate structure and between the first vertical spacer layer and the second vertical spacer layer.
Clause 2. The FET structure of clause 1, wherein the top-most nanosheet ribbon of the plurality of nanosheet ribbons comprises a first portion that contacts the first S/D EPI structure and a second portion that contacts the second S/D EPI structure but does not contact the first portion.
Clause 3. The FET structure of clause 2, wherein at least one of the first portion or the second portion comprises silicon, dielectric, or a combination thereof.
Clause 4. The FET structure of any of clauses 2 to 3, wherein the low-K dielectric structure extends between the first and second portions of the top-most nanosheet ribbon of the plurality of nanosheet ribbons.
Clause 5. The FET structure of any of clauses 1 to 4, further comprising a frontside gate contact disposed between the first vertical spacer and the second vertical spacer and extending through the low-K dielectric structure to contact the vertical metal gate structure.
Clause 6. The FET structure of any of clauses 1 to 5, further comprising a frontside inter-layer dielectric (ILD) layer disposed above the vertical metal gate structure, the first S/D EPI structure, and the second S/D EPI structure.
Clause 7. The FET structure of clause 6, further comprising a frontside S/D contact extending through the frontside ILD layer to contact the first S/D EPI structure or the second S/D EPI structure.
Clause 8. The FET structure of any of clauses 1 to 7, further comprising an etch stop material disposed on at least a bottom surface of the lower portion of the second S/D EPI structure.
Clause 9. The FET structure of clause 8, wherein the etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.
Clause 10. The FET structure of any of clauses 1 to 9, further comprising a backside ILD layer disposed below the vertical metal gate structure, the first S/D EPI structure, and the second S/D EPI structure.
Clause 11. The FET structure of any of clauses 1 to 10, wherein the gate structure comprises a gate-all-around (GAA) structure.
Clause 12. A method of fabricating a field effect transistor (FET) structure, the method comprising: providing a first source/drain (S/D) epitaxial (EPI) structure and a second S/D EPI structure set apart in a second horizontal direction; providing a vertical metal gate structure, extending in a first horizontal direction, being disposed between the first S/D EPI structure and the second S/D EPI structure, and comprising a channel structure, the channel structure comprising a plurality of nanosheet ribbons set apart in a vertical direction and extending in the first horizontal direction between the first S/D EPI structure and the second S/D EPI structure through the vertical metal gate structure that at least partially surrounds the plurality of nanosheet ribbons, wherein a top-most nanosheet ribbon of the plurality of nanosheet ribbons does not form a complete path to electrically connect the first S/D EPI structure to the second S/D EPI structure and wherein each of the other nanosheet ribbons of the plurality of nanosheet ribbons forms a complete path to electrically connect the first S/D EPI structure to the second S/D EPI structure; providing a high-K dielectric material disposed between the vertical metal gate structure and each of the plurality of nanosheet ribbons; providing a first vertical spacer layer extending in the first horizontal direction and disposed between the vertical metal gate structure and the first S/D EPI structure; providing a second vertical spacer layer extending in the first horizontal direction and disposed between the vertical metal gate structure and the second S/D EPI structure; and providing a low-K dielectric structure disposed above a top-most portion of the vertical metal gate structure and between the first vertical spacer layer and the second vertical spacer layer.
Clause 13. The method of clause 12, wherein the top-most nanosheet ribbon of the plurality of nanosheet ribbons comprises a first portion that contacts the first S/D EPI structure and a second portion that contacts the second S/D EPI structure but does not contact the first portion.
Clause 14. The method of clause 13, wherein at least one of the first portion or the second portion comprises silicon, dielectric, or a combination thereof.
Clause 15. The method of any of clauses 13 to 14, wherein the low-K dielectric structure extends between the first and second portions of the top-most nanosheet ribbon of the plurality of nanosheet ribbons.
Clause 16. The method of any of clauses 12 to 15, further comprising providing a frontside gate contact disposed between the first vertical spacer and the second vertical spacer and extending through the low-K dielectric structure to contact the vertical metal gate structure.
Clause 17. The method of any of clauses 12 to 16, further comprising providing a frontside inter-layer dielectric (ILD) layer disposed above the vertical metal gate structure, the first S/D EPI structure, and the second S/D EPI structure.
Clause 18. The method of clause 17, further comprising providing a frontside S/D contact extending through the frontside ILD layer to contact the first S/D EPI structure or the second S/D EPI structure.
Clause 19. The method of any of clauses 12 to 18, further comprising providing an etch stop material disposed on at least a bottom surface of the lower portion of the second S/D EPI structure.
Clause 20. The method of clause 19, wherein providing the etch stop material comprises providing at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.
Clause 21. The method of any of clauses 12 to 20, further comprising providing a backside ILD layer disposed below the vertical metal gate structure, the first S/D EPI structure, and the second S/D EPI structure.
Clause 22. The method of any of clauses 12 to 21, wherein providing the vertical metal gate structure comprises providing a gate-all-around (GAA) structure.
Clause 23. The method of any of clauses 12 to 22, wherein providing the vertical metal gate structure comprises: forming a stack of alternating silicon (Si) and silicon germanium (SiGe) layers; patterning the stack to form the silicon layers into silicon nanosheets separated by SiGe layers; etching the stack to create a gate stack between source/drain recesses; growing EPI structures from exposed silicon layers of the gate stack; removing a top-most silicon nanosheet; and performing a replacement metal gate process to replace the SiGe layers with gate metal.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A field effect transistor (FET) structure, comprising:
a first source/drain (S/D) epitaxial (EPI) structure and a second S/D EPI structure set apart in a second horizontal direction;
a vertical metal gate structure, extending in a first horizontal direction, being disposed between the first S/D EPI structure and the second S/D EPI structure, and comprising a channel structure, the channel structure comprising a plurality of nanosheet ribbons set apart in a vertical direction and extending in the first horizontal direction between the first S/D EPI structure and the second S/D EPI structure through the vertical metal gate structure that at least partially surrounds the plurality of nanosheet ribbons, wherein a top-most nanosheet ribbon of the plurality of nanosheet ribbons does not form a complete path to electrically connect the first S/D EPI structure to the second S/D EPI structure and wherein each of the other nanosheet ribbons of the plurality of nanosheet ribbons forms a complete path to electrically connect the first S/D EPI structure to the second S/D EPI structure;
a high-K dielectric material disposed between the vertical metal gate structure and each of the plurality of nanosheet ribbons;
a first vertical spacer layer extending in the first horizontal direction and disposed between the vertical metal gate structure and the first S/D EPI structure;
a second vertical spacer layer extending in the first horizontal direction and disposed between the vertical metal gate structure and the second S/D EPI structure; and
a low-K dielectric structure disposed above a top-most portion of the vertical metal gate structure and between the first vertical spacer layer and the second vertical spacer layer.

2. The FET structure of claim 1, wherein the top-most nanosheet ribbon of the plurality of nanosheet ribbons comprises a first portion that contacts the first S/D EPI structure and a second portion that contacts the second S/D EPI structure but does not contact the first portion.

3. The FET structure of claim 2, wherein at least one of the first portion or the second portion comprises silicon, dielectric, or a combination thereof.

4. The FET structure of claim 2, wherein the low-K dielectric structure extends between the first and second portions of the top-most nanosheet ribbon of the plurality of nanosheet ribbons.

5. The FET structure of claim 1, further comprising a frontside gate contact disposed between the first vertical spacer and the second vertical spacer and extending through the low-K dielectric structure to contact the vertical metal gate structure.

6. The FET structure of claim 1, further comprising a frontside inter-layer dielectric (ILD) layer disposed above the vertical metal gate structure, the first S/D EPI structure, and the second S/D EPI structure.

7. The FET structure of claim 6, further comprising a frontside S/D contact extending through the frontside ILD layer to contact the first S/D EPI structure or the second S/D EPI structure.

8. The FET structure of claim 1, further comprising an etch stop material disposed on at least a bottom surface of the lower portion of the second S/D EPI structure.

9. The FET structure of claim 8, wherein the etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

10. The FET structure of claim 1, further comprising a backside ILD layer disposed below the vertical metal gate structure, the first S/D EPI structure, and the second S/D EPI structure.

11. The FET structure of claim 1, wherein the gate structure comprises a gate-all-around (GAA) structure.

12. A method of fabricating a field effect transistor (FET) structure, the method comprising:
providing a first source/drain (S/D) epitaxial (EPI) structure and a second S/D EPI structure set apart in a second horizontal direction;
providing a vertical metal gate structure, extending in a first horizontal direction, being disposed between the first S/D EPI structure and the second S/D EPI structure, and comprising a channel structure, the channel structure comprising a plurality of nanosheet ribbons set apart in a vertical direction and extending in the first horizontal direction between the first S/D EPI structure and the second S/D EPI structure through the vertical metal gate structure that at least partially surrounds the plurality of nanosheet ribbons, wherein a top-most nanosheet ribbon of the plurality of nanosheet ribbons does not form a complete path to electrically connect the first S/D EPI structure to the second S/D EPI structure and wherein each of the other nanosheet ribbons of the plurality of nanosheet ribbons forms a complete path to electrically connect the first S/D EPI structure to the second S/D EPI structure;
providing a high-K dielectric material disposed between the vertical metal gate structure and each of the plurality of nanosheet ribbons;
providing a first vertical spacer layer extending in the first horizontal direction and disposed between the vertical metal gate structure and the first S/D EPI structure;
providing a second vertical spacer layer extending in the first horizontal direction and disposed between the vertical metal gate structure and the second S/D EPI structure; and
providing a low-K dielectric structure disposed above a top-most portion of the vertical metal gate structure and between the first vertical spacer layer and the second vertical spacer layer.

13. The method of claim 12, wherein the top-most nanosheet ribbon of the plurality of nanosheet ribbons comprises a first portion that contacts the first S/D EPI structure and a second portion that contacts the second S/D EPI structure but does not contact the first portion.

14. The method of claim 13, wherein at least one of the first portion or the second portion comprises silicon, dielectric, or a combination thereof.

15. The method of claim 13, wherein the low-K dielectric structure extends between the first and second portions of the top-most nanosheet ribbon of the plurality of nanosheet ribbons.

16. The method of claim 12, further comprising providing a frontside gate contact disposed between the first vertical spacer and the second vertical spacer and extending through the low-K dielectric structure to contact the vertical metal gate structure.

17. The method of claim 12, further comprising providing a frontside inter-layer dielectric (ILD) layer disposed above the vertical metal gate structure, the first S/D EPI structure, and the second S/D EPI structure.

18. The method of claim 17, further comprising providing a frontside S/D contact extending through the frontside ILD layer to contact the first S/D EPI structure or the second S/D EPI structure.

19. The method of claim 12, further comprising providing an etch stop material disposed on at least a bottom surface of the lower portion of the second S/D EPI structure.

20. The method of claim 19, wherein providing the etch stop material comprises providing at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

21. The method of claim 12, further comprising providing a backside ILD layer disposed below the vertical metal gate structure, the first S/D EPI structure, and the second S/D EPI structure.

22. The method of claim 12, wherein providing the vertical metal gate structure comprises providing a gate-all-around (GAA) structure.

23. The method of claim 12, wherein providing the vertical metal gate structure comprises:
forming a stack of alternating silicon (Si) and silicon germanium (SiGe) layers;
patterning the stack to form the silicon layers into silicon nanosheets separated by SiGe layers;
etching the stack to create a gate stack between source/drain recesses;
growing EPI structures from exposed silicon layers of the gate stack;
removing a top-most silicon nanosheet; and
performing a replacement metal gate process to replace the SiGe layers with gate metal.
